(19) United States
(12) Patent Application Publication
(10) Pub. No.: US 2015/0200521 A1
(43) Pub. Date: Jul. 16, 2015

(54) NITRIDE SEMICONDUCTOR LIGHT EMITTING ELEMENT

(71) Applicant: Sumitomo Electric Industries, Ltd., Osaka-shi (JP)

(72) Inventors: Masahiro Adachi, Osaka-shi (JP); Takumi Yonemura, Osaka-shi (JP)

(21) Appl. No.: 14/412,156

(22) PCT Filed: Mar. 26, 2014
(86) PCT No.: PCT/JP2014/058565

§ 371 Date: Dec. 30, 2014

(30) Foreign Application Priority Data
May 24, 2013 (JP) 2013-109743

(51) Int. Cl. H01S 5/343; H01S 5/323

(52) U.S. Cl. CPC H01S 5/343; H01S 5/323

(57) ABSTRACT

A nitride semiconductor light emitting element includes a support base and an epitaxial layer. A p-type dopant is added to a p-side cladding layer of the epitaxial layer, to which a p-side electrode is bonded. The p-type dopant is Mg. An X-ray absorption fine structure spectrum of the p-side cladding layer includes a peak P1 and a peak P2. The peak P1 is a first peak on the high energy side from a K absorption edge of incident X-rays, and the peak P2 is next to the peak P1 on the high energy side and is a second peak on the high energy side from the K absorption edge of the incidence X-rays. A ratio of a value of the peak P1 to a value of the peak P2 is in a range of 70[%] or more and 200[%] or less.

### BACKGROUND OF THE INVENTION

1. Technical Field

The present invention relates to a nitride semiconductor light emitting element.

2. Background Art

Patent Literature 1 discloses a technology for realizing p-type conduction. The technology of Patent Literature 1 is a technology for uniformly forming a p-type gallium nitride-based semiconductor having low resistance on a wafer surface, in which a gallium nitride (GaN)-based semiconductor containing magnesium (Mg) added as acceptor impurities is annealed at temperature more than 400[° C.] in nitrogen atmosphere. Difficulty of p-type conduction of the nitride semiconductor is considered to be result from inactivation of Mg added as the acceptor impurities due to a coupling to hydrogen (H). In the technology of Patent Literature 1, the coupling between Mg and hydrogen is broken to realize a gallium nitride-based semiconductor in which difficulty in the p-type conduction is mitigated.

### CITATION LIST

### Patent Literature

Patent Literature 1: Japanese Patent No. 2540791

### SUMMARY OF INVENTION

### Problem to be Solved by the Invention

Meanwhile, a green LD (LD: laser diode) has a problem in that an operation voltage increases due to electrical energization. Inactivation of the acceptor impurities Mg caused by residual hydrogen atoms in the gallium nitride-based semiconductor has been widely recognized as a cause of such voltage increase related to the green LD. However, other causes of inactivation not caused by the residual hydrogen atoms have not been explained. Therefore, an object of the present invention has been made in view of the above circumstances, and is to provide a nitride semiconductor light emitting element including a p-type nitride semiconductor in which increase in operation voltage due to electrical energization is suppressed.

### Means for Solving the Problem

A nitride semiconductor light emitting element according to an aspect of the present invention includes a support base; and an epitaxial layer, wherein both the support base and the epitaxial layer are composed of a hexagonal group-III nitride semiconductor, the epitaxial layer includes a light emitting layer of a quantum well and a cladding layer and are provided on a main surface of the support base, a p-type dopant is added to the cladding layer, the p-type dopant is Mg, an X-ray absorption fine structure spectrum of the cladding layer includes a first peak and a second peak, the first peak is a first peak on the high energy side from a K absorption edge of incident X-rays, the second peak is next to the first peak on the high energy side of the incident X-ray and is a second peak on the high energy side from the K absorption edge of the incidence X-rays, and a ratio of a value of the first peak to a value of the second peak is in a range of 70[%] or more and 200[%] or less. For example, for the practical use of a green LD, it is essential to realize the p-type nitride semiconductor in which the increase in operation voltage due to electrical energization is suppressed and overcome. The inventors have considered that a phenomenon in which the point defects activated due to a non-luminous recombination of electrons and holes due to electrical energization are coupled with acceptor impurities Mg, and the acceptor impurities Mg become inactivated is a main cause of the increase in the operation voltage. Therefore, the inventors have extensively studied a scheme of analyzing a state of the Mg in the nitride semiconductor, found the state analysis scheme using X-ray absorption fine structure analysis, and found that the increase in the operation voltage due to electrical energization can be suppressed in the case of the X-ray absorption fine structure spectrum of the above aspect of the present invention.

A nitride semiconductor light emitting element according to another aspect of the present invention includes a support base; and an epitaxial layer, wherein both the support base and the epitaxial layer are composed of a hexagonal group-III nitride semiconductor, the epitaxial layer includes a light emitting layer of a quantum well and a cladding layer and are provided on a main surface of the support base, a p-type dopant is added to the cladding layer, the p-type dopant is Mg, a hydrogen concentration of the cladding layer is in a range less than 2×10¹⁷ [cm⁻³], and concentration of point defects of the cladding layer is in a range less than 1×10¹⁶[cm⁻³]. For example, for the practical use of a green LD, it is essential to realize the p-type nitride semiconductor in which the increase in operation voltage due to electrical energization is suppressed and overcome. The inventors have considered that a phenomenon in which the point defects activated due to a non-luminous recombination of electrons and holes due to electrical energization are coupled with acceptor impurities Mg, and the acceptor impurities Mg become inactivated is a main cause of the increase in the operation voltage. Therefore, the inventors have extensively studied a scheme of analyzing a state of the Mg in the nitride semiconductor, found the state analysis scheme using X-ray absorption fine structure analysis, and found that the increase in the operation voltage due to electrical energization can be suppressed in the case of the X-ray absorption fine structure spectrum of the another aspect of the present invention.

### Effects of the Invention

According to the present invention, it is possible to provide the nitride semiconductor light emitting element including a p-type nitride semiconductor in which the increase in operation voltage due to electrical energization is suppressed.

### BRIEF DESCRIPTION OF DRAWINGS

FIG. 1 is a diagram illustrating a configuration of a nitride semiconductor light emitting element according to the embodiment.

FIG. 2 is a diagram illustrating a layered structure of the nitride semiconductor light emitting element according to the embodiment.

FIG. 3 is a diagram used to describe characteristics of the nitride semiconductor light emitting element according to the embodiment.

FIG. 4 is a diagram used to describe a method of measuring characteristics of the nitride semiconductor light emitting element according to the embodiment.

FIG. 5 is a diagram used to describe a method of measuring characteristics of the nitride semiconductor light emitting element according to the embodiment.

FIG. 6 is a diagram illustrating a verification result for Example.

FIG. 7 is a diagram illustrating a verification result for Example.

FIG. 8 is a diagram illustrating a verification result for Example.

### DESCRIPTION OF THE EMBODIMENTS

(Description of Embodiment of the Present Invention)

Content of an embodiment of the present invention will first be listed and described. A nitride semiconductor light emitting element according to one embodiment of the present invention includes a support base; and an epitaxial layer, wherein both the support base and the epitaxial layer are composed of a hexagonal group-III nitride semiconductor, the epitaxial layer includes a light emitting layer of a quantum well and a cladding layer and are provided on a main surface of the support base, a p-type dopant is added to the cladding layer, the p-type dopant is Mg, an X-ray absorption fine structure spectrum of the cladding layer includes a first peak and a second peak, the first peak is a first peak on the high energy side from a K absorption edge of incident X-rays, the second peak is next to the first peak on the high energy side of the incident X-ray and is a second peak on the high energy side from the K absorption edge of the incidence X-rays, and a ratio of a value of the first peak to a value of the second peak is in a range of 70[%] or more and 200[%] or less. For example, for the practical use of a green LD, it is essential to realize the p-type nitride semiconductor in which the increase in operation voltage due to electrical energization is suppressed and overcome. The inventors have considered that a phenomenon in which the point defects activated due to a non-luminous recombination of electrons and holes due to electrical energization are coupled with acceptor impurities Mg, and the acceptor impurities Mg become inactivated is a main cause of the increase in the operation voltage. Therefore, the inventors have extensively studied a scheme of analyzing a state of the Mg in the nitride semiconductor, found the state analysis scheme using X-ray absorption fine structure analysis, and found that the increase in the operation voltage due to electrical energization can be suppressed in the case of the X-ray absorption fine structure spectrum of the above embodiment of the present invention.

In the nitride semiconductor light emitting element according to the above embodiment of the present invention, the first peak in the X-ray absorption fine structure spectrum of the cladding layer may be generated between 1300 [eV] and 1309 [eV] of incident X-ray energy, and the second peak in the X-ray absorption fine structure spectrum of the cladding layer may be generated between 1309 [eV] and 1320 [eV] of the incident X-ray energy.

In the nitride semiconductor light emitting element according to the above embodiment of the present invention, Mg concentration of the cladding layer may be equal to or more than 1×10¹⁸ [cm⁻³] and equal to or less than 5×10²¹ [cm⁻³].

In the nitride semiconductor light emitting element according to the above embodiment of the present invention, hydrogen concentration of the cladding layer may be in a range less than 2×10¹⁷ [cm⁻³], and concentration of point defects of the cladding layer may be in a range less than 1×10¹⁶ [cm⁻³].

In the nitride semiconductor light emitting element according to the above embodiment of the present invention, thermal activation energy of the point defects may be in a range of 0.1 [eV] or more and 1.7 [eV] or less. When the thermal activation energy of the point defects is in this range, carriers are bound in a deep level, which is a cause of reduction of effective carrier concentration.

In the nitride semiconductor light emitting element according to the above embodiment of the present invention, the main surface of the support base may be semi-polar, and the main surface may be inclined at an angle in any one of a range of 10° or more and 80° or less and a range of 100° or more and 170° or less with respect to a c plane of the hexagonal group-III nitride semiconductor. In this range of the plane direction, point defects specific to the plane direction is introduced. The point defects become a main factor of the increase in voltage. The point defects refer to Ga holes, nitrogen holes, atoms between Ga lattices, atoms between nitrogen lattices, and composition defects in which they and the impurity atom Mg are coupled.

In the nitride semiconductor light emitting element according to the above embodiment of the present invention, the main surface of the support base may be semi-polar, and the main surface may be inclined at an angle in any one of a range of 63° or more and 80° or less and a range of 100° or more to 117° or less with respect to a c plane of the hexagonal group-III nitride semiconductor. In this range of the plane direction, crystal growth of a high-In composition can be realized with higher crystal quality than the c plane, a nonpolar plane, and a semi-polar a plane. The a plane is a {11-20} plane, and the semi-polar a plane is a plane inclined in a c-axis direction from the a plane and is, for example, a {11-22} plane.

A nitride semiconductor light emitting element according to another embodiment of the present invention includes a support base; and an epitaxial layer, wherein both the support base and the epitaxial layer are composed of a hexagonal group-III nitride semiconductor, the epitaxial layer includes a light emitting layer of a quantum well and a cladding layer and are provided on a main surface of the support base, a p-type dopant is added to the cladding layer, the p-type dopant is Mg, a hydrogen concentration of the cladding layer is in a range less than 2×10¹⁷ [cm⁻³], and concentration of point defects of the cladding layer is in a range less than 1×10¹⁶[cm⁻³]. For example, for the practical use of a green LD, it is essential to realize the p-type nitride semiconductor in which the increase in operation voltage due to electrical energization is suppressed and overcome. The inventors have considered that a phenomenon in which the point defects activated due to a non-luminous recombination of electrons and holes due to electrical energization are coupled with acceptor impurities Mg, and the acceptor impurities Mg become inactivated is a main cause of the increase in the operation voltage. Therefore, the inventors have extensively studied a scheme of analyzing a state of the Mg in the nitride semiconductor, found the state analysis scheme using X-ray absorption fine structure analysis, and found that the increase in the operation voltage due to electrical energization can be suppressed in the case of the X-ray absorption fine structure spectrum of the above another embodiment of the present invention.

In the nitride semiconductor light emitting element according to the above another embodiment of the present invention, the Mg concentration of the cladding layer may be equal to or more than 1×10¹⁸ [cm⁻³] and equal to or less than 5×10²¹ [cm⁻³].

In the nitride semiconductor light emitting element according to the above another embodiment of the present invention, thermal activation energy of the point defects may be in a range of 0.1 [eV] or more and 1.7 [eV] or less.

In the nitride semiconductor light emitting element according to the above another embodiment of the present invention, the main surface of the support base may be semi-polar, and the main surface may be inclined at an angle in any one of a range of 10° or more and 80° or less and a range of 100° or more and 170° or less with respect to a c plane of the hexagonal group-III nitride semiconductor.

In the nitride semiconductor light emitting element according to the above another embodiment of the present invention, the main surface of the support base may be semi-polar, and the main surface may be inclined at an angle in any one of a range of 63° or more and 80° or less and a range of 100° or more to 117° or less with respect to a c plane of the hexagonal group-III nitride semiconductor.

(Details of Embodiment of the Present Invention)

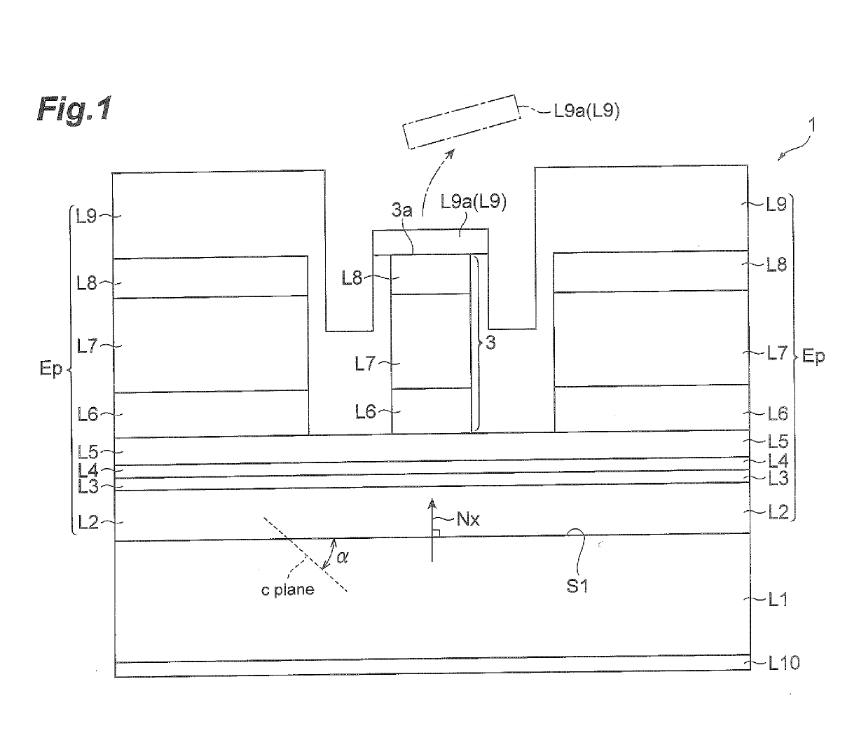

Hereinafter, a preferred embodiment according to the present invention will be described in detail with reference to the drawings. Further, the same elements are denoted with the same signs in the description of the drawings and repeated description is omitted, if possible. The inventors have intensively studied a scheme of analyzing a state of Mg (p type dopant) of a nitride semiconductor, found a the state analysis scheme using an X-ray absorption fine structure analysis, and realized a p-type nitride semiconductor device in which increase in energization voltage is suppressed. The nitride semiconductor light emitting element 1 according to this embodiment is a ridge waveguide type LD fabricated on a GaN single crystal substrate of a semi-polar plane, and includes a configuration illustrated in FIG. 1. The nitride semiconductor light emitting element 1 outputs a green laser.

FIG. 1 is a diagram illustrating a configuration of a nitride semiconductor light emitting element according to an embodiment. FIG. 1 illustrates an internal layered structure in a nitride semiconductor light emitting element 1 viewed along a surface perpendicular to an extending direction of a waveguide of the nitride semiconductor light emitting element 1. The nitride semiconductor light emitting element 1 includes a support base L1, an epitaxial layer Ep, a p-side electrode L9, and an n-side electrode L10, as illustrated in FIG. 1. The support base L1 and the epitaxial layer Ep are both hexagonal group-III nitride semiconductors. The epitaxial layer Ep is provided on a main surface S1 of the support base L1. The p-side electrode L9 is bonded to the epitaxial layer Ep, and the n-side electrode L10 is bonded to the support base L1. The epitaxial layer Ep includes an n-side cladding layer L2, an n-side guide layer L3, a light emitting layer L4, a p-side guide layer L5, a p-side guide layer L6, a p-side cladding layer L7, a contact layer L8, and the p-side electrode L9. The n-side cladding layer L2, the n-side guide layer L3, the light emitting layer L4, the p-side guide layer L5, the p-side guide layer L6, the p-side cladding layer L7, and the contact layer L8 are provided sequentially on the main surface S1 of the support base L1. The light emitting layer L4 includes a quantum well.

The main surface S1 is inclined at an angle α with respect to a c plane of the hexagonal group-III nitride semiconductor. The angle α can be in any one of a range from 10° or more to 80° or less and a range from 100° or more to 170° or less. The angle α can also be in any one of a range from 63° or more to 80° or less and a range from 100° or more to 117° or less. The main surface S1 can be, for example, a semi-polar (20-21) plane of the hexagonal group-III nitride semiconductor.

The epitaxial layer Ep includes a ridge waveguide 3. A portion of the p-side guide layer L6, a portion of the p-side cladding layer L7, and a portion of the contact layer L8 in the epitaxial layer Ep constitute the ridge waveguide 3. The ridge waveguide 3 is provided on the p-side guide layer L5 to extend in a normal direction Nx of the main surface S1. The p-side electrode L9 extends to cover two side surfaces of the ridge waveguide 3, and a surface of the p-side guide layer L5 on the side of each of the two side surfaces of the ridge waveguide 3. The two side surfaces of the ridge waveguide 3 extend in the extending direction of the waveguide to be perpendicular to the main surface S1. The p-side electrode L9 includes a ridge portion electrode L9a. The ridge portion electrode L9a is provided on an end portion 3a of the ridge waveguide 3 and bonded to the end portion 3a of the ridge waveguide 3. The p-side electrode L9 is bonded to the contact layer L8 of the epitaxial layer Ep. The ridge portion electrode L9a of the p-side electrode L9 is particularly bonded to the end surface of the contact layer L8 of the epitaxial layer Ep in the ridge waveguide 3. The n-side electrode L10 is provided on the back surface (a surface on the opposite side of the main surface S1) of the support base L1.

A material of the support base L1 to the contact layer L8 is an III-V group nitride semiconductor. The material of the support base L1 is, for example, n-InAlGaN. The material of the n-side cladding layer L2 is, for example, n-GaN. Alternatively, the material of the n-side cladding layer L2 can be n-InGaN. The material of the n-side guide layer L3 is, for example, i-InGaN. Alternatively, the material of the n-side guide layer L3 can be i-GaN. The material of the light emitting layer L4 is, for example, i-InGaN. The material of the p-side guide layer L5 is, for example, i-InGaN. Alternatively, the material of the p-side guide layer L5 can be i-GaN. The material of the p-side guide layer L6 is, for example, p-GaN. Alternatively, the material of the p-side guide layer L6 can be p-InGaN. A p-type dopant of the p-side guide layer L6 is Mg. The material of the p-side cladding layer L7 is, for example, p-AlGaN. Alternatively, the material of the p-side cladding layer L7 can be p-InAlGaN. A p-type dopant of the p-side cladding layer L7 is Mg. The material of the contact layer L8 is, for example, p-GaN. Mg concentration in the p-side cladding layer L7 is equal to or more than 1×10¹⁸ [cm⁻³] and equal to or less than 5×10²¹ [cm⁻³]. A thickness of the p-side cladding layer L7 is equal to or more than about 1 [nm] and equal to or less about 1000 [nm]. When a composition of In is x, a composition of Al is y, and a composition of Ga is 1−x−y, a composition of the p-side cladding layer L7 is InₓAl_{y}Ga_{1-x-y}N (x is equal to or more than 0 and equal to or less than 1.0, y is equal to or more than 0 and equal to or less than 1.0, and x+y≦1). In the case of such a composition of the p-side cladding layer L7, good optical confinement in the semi-polar m plane including (20-21) is obtained, and is suitable for a low threshold oscillation. On the other hand, defects due to the plane in this plane direction are easy to enter. The m plane is a {20-20} plane, and the semi-polar m plane is a semi-polar plane inclined in the c-axis direction from the m plane and, for example, is a semi-polar {20-21} plane.

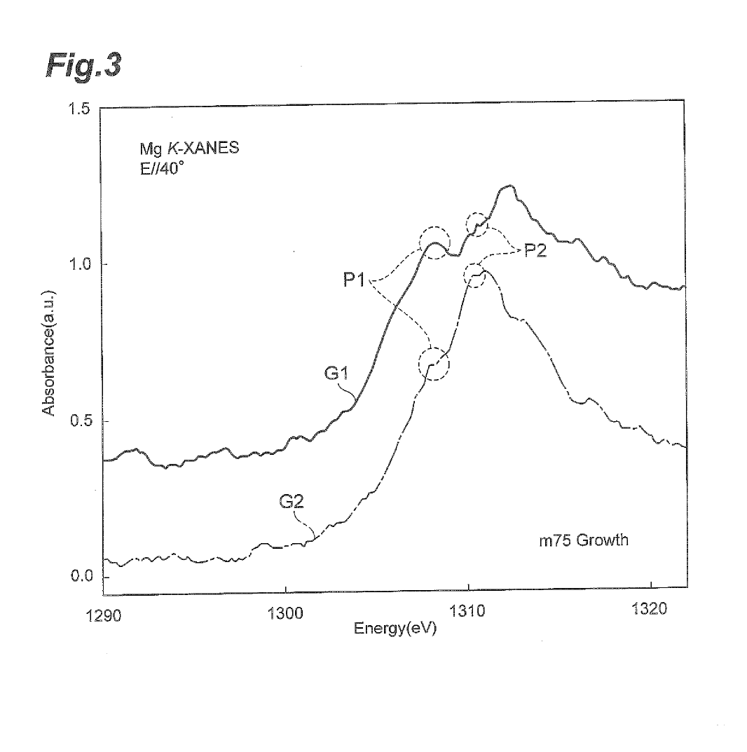

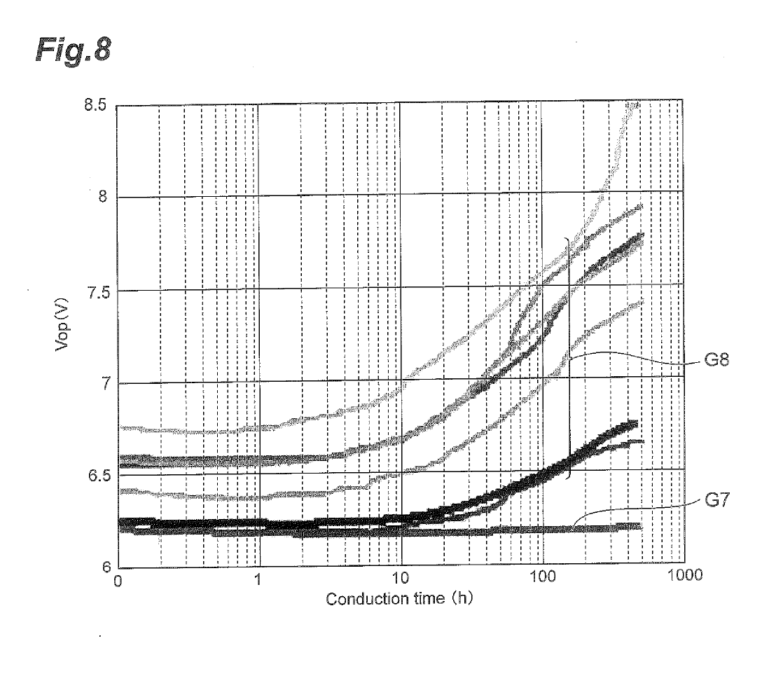

The p-side cladding layer L7 of the nitride semiconductor light emitting element 1 has an XAFS spectrum that is the same as a measurement result G1 of FIG. 3 to be described below. In the nitride semiconductor light emitting element 1 including the p-side cladding layer L7 having the XAFS spectrum that is the same as the measurement result G1, the increase in the operation voltage due to electrical energization is well suppressed, as illustrated in a graph G7 of FIG. 8 to be describe below.

### EXAMPLE

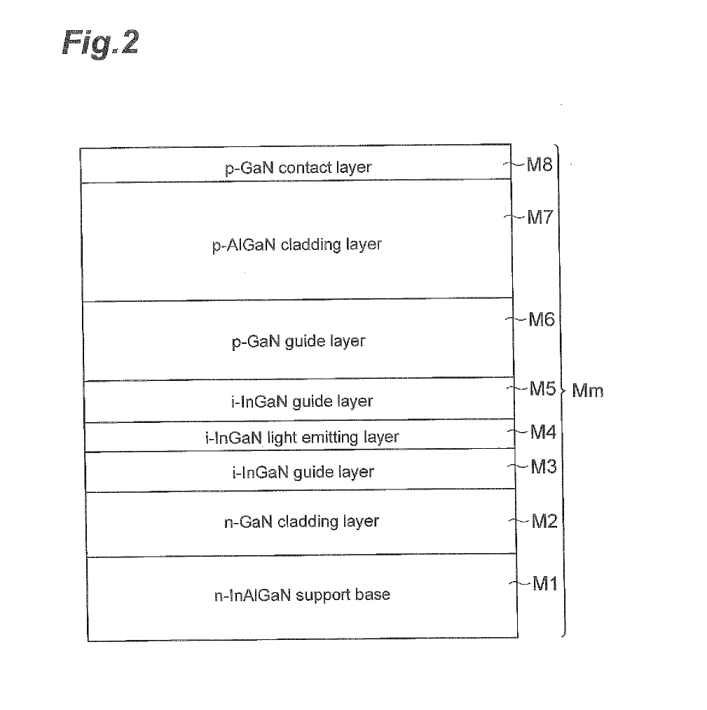

A method of manufacturing the nitride semiconductor light emitting element 1 will be described with reference to FIG. 2. A main surface of an n-InAlGaN support base M1 is a surface inclined at 75° with respect to a c plane in an m axis direction, and is a semi-polar (20-21) plane. The n-InAlGaN support base M1 is stored in a growth reactor and crystal growth is performed through epitaxial growth on the main surface of the n-InAlGaN support base M1. The following layers were sequentially epitaxially grown on the main surface of the n-InAlGaN support base M1 using trimethyl gallium, trimethyl aluminum, and ammonia as feed gases of base materials, using silane and trimethyl magnesium as a raw material for an n or p type additive. That is, an n-GaN cladding layer M2, an i-InGaN guide layer M3, an i-InGaN light emitting layer M4, an i-InGaN guide layer M5, a p-GaN guide layer M6, a p-AlGaN cladding layer M7, and a p-GaN contact layer M8 were epitaxially grown on the main surface of the n-InAlGaN support base M1. Also, a substrate product Mm including the n-InAlGaN support base M1, the n-GaN cladding layer M2, the i-InGaN guide layer M3, the i-InGaN light emitting layer M4, the i-InGaN guide layer M5, the p-GaN guide layer M6, the p-AlGaN cladding layer M7, and the p-GaN contact layer M8 was fabricated through such epitaxial growth on the main surface of the n-InAlGaN support base M1.

The n-GaN cladding layer M2 can also be a cladding layer formed of n-InGaN. The i-InGaN guide layer M3 can also be a guide layer formed of i-GaN. The i-InGaN guide layer M5 can also be a guide layer formed of i-GaN. The p-GaN guide layer M6 can be a guide layer formed of p-InGaN. The p-AlGaN cladding layer M7 can also be a cladding layer formed of p-InAlGaN.

A ridge waveguide type LD (ridge width: 2 μm) corresponding to the nitride semiconductor light emitting element 1 was fabricated from this substrate product Mm using a photolithography technology and a dry etching technology. Also, an Au/Pt/Ti/Pd electrode was provided as the p-side electrode corresponding to the p-side electrode L9 (including the ridge portion electrode L9a). Then, an ohmic electrode was formed as an n-side electrode corresponding to the n-side electrode L10 by polishing and dry-etching a back surface (a surface on the opposite side of the main surface) of the n-InAlGaN support base M1 and depositing Au/Ti/Al using a combination of an EB deposition method and a resistance heating method. Then, the substrate product in which the ridge waveguide, the p-side electrode, and the n-side electrode were provided was cleaved so that a resonator length is 500 μm, and divided into an LD chip so as to form the nitride semiconductor light emitting element 1 which is the LD chip. This nitride semiconductor light emitting element 1 was mounted to a stem.

Next, Example and a comparative example were verified in detail through Verifications 1 to 4 below. Example and the comparative example differ only in growth environment of the epitaxial growth, and a manufacturing process, and include the same layered structure. Conditions of the crystal growth according to Example in the growth reactor described above differ from growth environment according to the comparative example in the growth reactor in the related art. Example is an element which corresponds to the nitride semiconductor light emitting element 1 and from which the measurement result G1 of FIG. 3 is obtained. The comparative example is an element which corresponds to a nitride semiconductor light emitting element in the related art and from which a measurement result G2 of FIG. 3 is obtained. Hereinafter, the same names except for the signs and material names in Example and the comparative example are used for each configuration of the comparative example corresponding to each configuration of Example in description of Verifications 1 to 4.

(Verification 1)

Example is an example after electrical energization for 100 [h] (h: hour) at a current of 300 [mA]. An operation voltage in Example was increased by +0.02 [V] from an initial operation voltage after the electrical energization in Example. Comparative Examples 1 and 2 were prepared as comparative examples. Comparative Example 1 is a comparative example of non-electrical energization, and Comparative Example 2 is a comparative example after electrical energization for 100 [h] at current of 300 [mA]. An operation voltage of Comparative Example 2 was increased by +0.53 [V] from an initial operation voltage after electrical energization in Comparative Example 1. The initial operation voltage after the electrical energization in Comparative Example 1 was equal to the initial operation voltage after the electrical energization in Example.

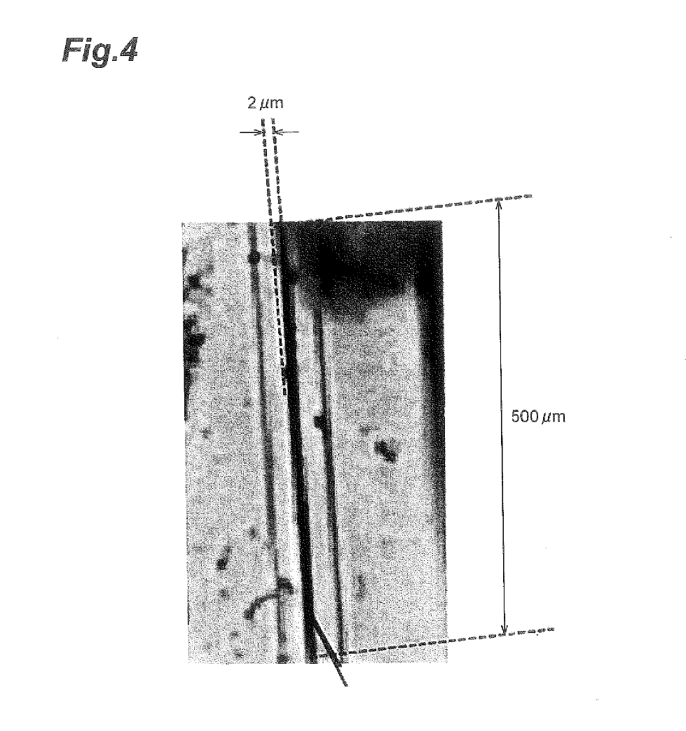

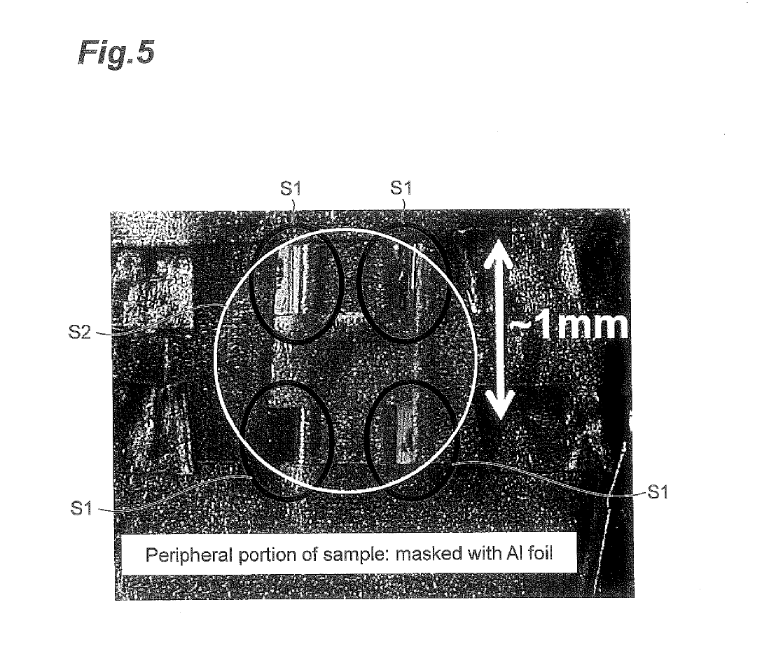

Then, the ridge portion electrode on the ridge waveguide was removed by performing wet etching using aqua regia on each of samples of Example, Comparative Example 1, and Comparative Example 2, as illustrated in FIGS. 1 and 4. FIG. 4 is a photograph obtained by photographing the ridge waveguide after the ridge portion electrode has been removed, from on the main surface of the support base. Also, four Examples were prepared and arranged in a square lattice form as indicated by a sign S1 in FIG. 5 so as to obtain four times signal intensity of Example. In each of Comparative Examples 1 and 2, four comparative examples were arranged as indicated by the sign S1 in FIG. 5 so as to obtain four times signal intensity of each of Comparative Examples 1 and 2. Further, in any of the Example, Comparative Example 1, and Comparative Example 2, portions other than the ridge waveguide were masked with an Al foil so as to suppress signals of the portions other than the ridge waveguide, as illustrated in FIG. 5.

As described above, Example, Comparative Example 1, and Comparative Example 2 were irradiated with incident X-rays from the main surface of the support base to measure an X-ray absorption fine structure spectrum (XAFS spectrum) of Mg in the p-type contact layer of a conduction portion of the ridge waveguide. An area indicated by a sign S2 in FIG. 5 was irradiated with the incident X-rays. A measurement result of the XAFS spectrum is illustrated in FIG. 3. A horizontal axis of FIG. 3 indicates energy [eV] of the incident X-rays, and a vertical axis of FIG. 3 indicates an X-ray absorbance [a.u.] of the incident X-rays. The measurement result G1 of FIG. 3 is a measurement result of the XAFS signal of Example, and the measurement result G2 of FIG. 3 is a measurement result of the XAFS signal of Comparative Example 2. The measurement result of the XAFS signal of Comparative Example 1 is the same as the measurement result G1. The measurement result illustrated in FIG. 3 was obtained by inclining a polarization vector E of the incident X-rays at 40° with respect to the c axis.

In FIG. 3, the X-ray absorption fine structure spectrum for the contact layer on the p side includes a first peak (peak P1) and a second peak (peak P2). The peak P1 is a first peak on the high energy side from a K absorption edge (about 1303 [eV]) of Mg in FIG. 3. The peak P2 is next to the peak P1 on the high energy side, and is a second peak on the high energy side from the K absorption edge of the incident X-rays. In the peak P1, the measurement result G1 according to Example projects relative to the measurement result G2 according to Comparative Example 2. In the peak P2, the measurement result G2 according to Comparative Example 2 projects relative to the measurement result G1 according to Comparative Example 1. In FIG. 3, the peak P1 was generated between 1300 [eV] and 1309 [eV] of the incident X-ray energy, and the peak P2 is generated between 1309 [eV] and 1320 [eV] of the incident X-ray energy.

Thus, in FIG. 3, the measurement result G1 according to Example and the measurement result G2 according to Comparative Example 2 distinctly differed in the peak P1 and the peak P2. Further, in Example, when the X-ray absorbance in a location corresponding to the peak P1 was M1, the X-ray absorbance in a location for the peak P2 was M2, and a ratio of M1 to M2 (M1/M2×100[%]) was equal to or more than 70[%] and equal to or less than 200[%], the increase in the operation voltage due to the electrical energization was preferably suppressed, as shown in a graph G7 of FIG. 8 to be describe below, as a result of having measured a plurality of measurements that are the same as the measurement having obtained the result of FIG. 3.

Reasons of the suppression of the increase in operation voltage of the electrical energization in Example will be described. In Comparative Example 2 after the electrical energization in the related art, point defects in the contact layer on the p side are activated by a non-light emitting recombination of electrons and holes due to current injection. Also, it is considered that the activated point defects is coupled to Mg acceptors and the Mg acceptors become inactivated, such that the XAFS spectrum of Comparative Example 2 differs from the XAFS spectrum (the same graph as the measurement result G1) of Comparative Example 1 of non-electrical energization in the related art. That is, it is considered that a difference between Example (or Comparative Example 1) and Comparative Example 2 in the XAFS spectrum is in initial concentration of the point defects. It is considered that the difference in the initial concentration (at the time of non-electrical energization) of the point defects in Example and Comparative Example 2 distinctly appears as a difference in XAFS spectrum due to electrical energization.

(Verification 2)

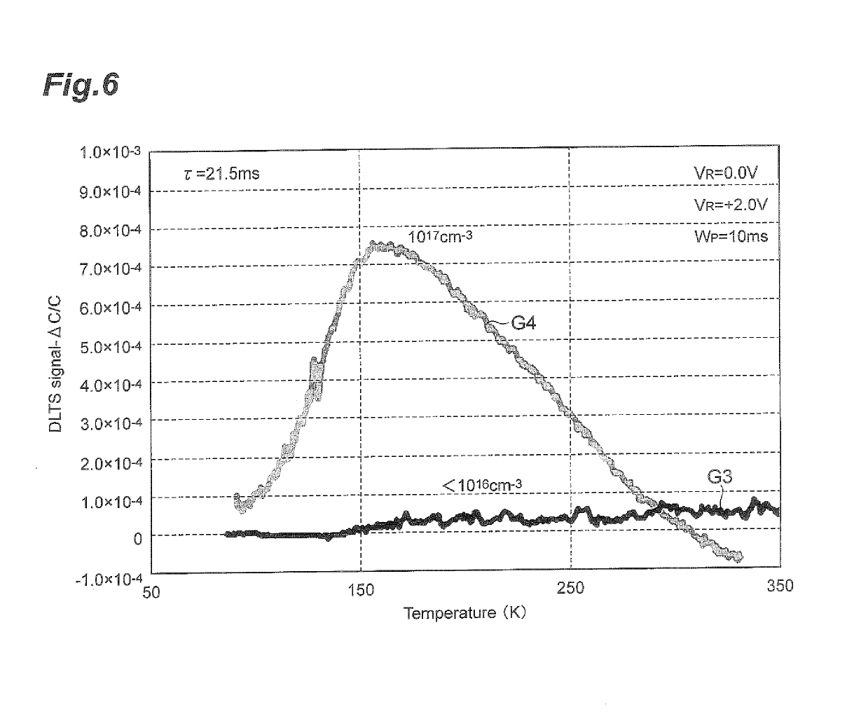

In Verification 2, a range of the concentration of point defects of Example and the comparative example and a level of the point defects in the p-type layer and, particularly, the cladding layer were estimated. A result of Verification 2 is illustrated in FIG. 6. The measurement result illustrated in FIG. 6 is a measurement result for the cladding layer. A measurement result G3 shows a measurement result of Example. A measurement result G4 shows a measurement result of the comparative example. A horizontal axis of FIG. 6 indicates a temperature [K] of an element which is a measurement target. A vertical axis of FIG. 6 indicates a DLTS signal-ΔC/C, and a value obtained by multiplying this value by carrier concentration at the time of measurement corresponds to the defect concentration. ΔC indicates a peak strength of the DLTS signal (in FIG. 6, a value at 160 [K] is the peak value), and C indicates capacitance when a reverse bias is applied at a temperature (in FIG. 6, 160 [K]) corresponding to this peak value. The result illustrated in FIG. 6 was obtained under the following conditions: rate window τ=21.5 [ms], a reverse bias V_{R}=0.0 [V] and +2.0 [V], and a pulse width of a forward pulse voltage Wₚ=10 [ms]. The rate window is a time constant for monitoring carrier release from the point defects.

It can be seen from the measurement result G3 that the defect concentration of Example is below 10¹⁶[cm⁻³] when the temperature of Example is in at least a range of 150 [K] to 200 [K]. Therefore, it can be seen in Example that the concentration of point defects of the energy corresponding to the temperature range of 150 [K] to 200 [K] is about 10¹⁶ [cm⁻³] (or below 10¹⁶ [cm⁻³]). On the other hand, it can be seen from the measurement result G4 that the concentration of the point defects of the comparative example is about 1×10¹⁷ [cm⁻³] when the temperature of the comparative example is in a range of at least 150 [K] to 200 [K], and a peak of the concentration of the point defects is in a temperature range of 130 [K] to 250 [K]. Therefore, it can be seen in the comparative example that there are point defects at the concentration of less than about 1×10¹⁶ [cm⁻³] in thermal activation energy ΔE corresponding to the temperature range of 130 [K] to 250 [K]. Thus, it can be seen that the point defects of the thermal activation energy ΔE is greatly reduced in Example relative to the comparative example. ΔE is a thermal barrier of carriers bound to the defect level, and is defined as thermal activation energy in carrier release of the defect level. At this time, detected ΔE of the temperature area is equal to or more than 0.1 [eV] and equal to or less than 1.7 [eV].

(Verification 3)

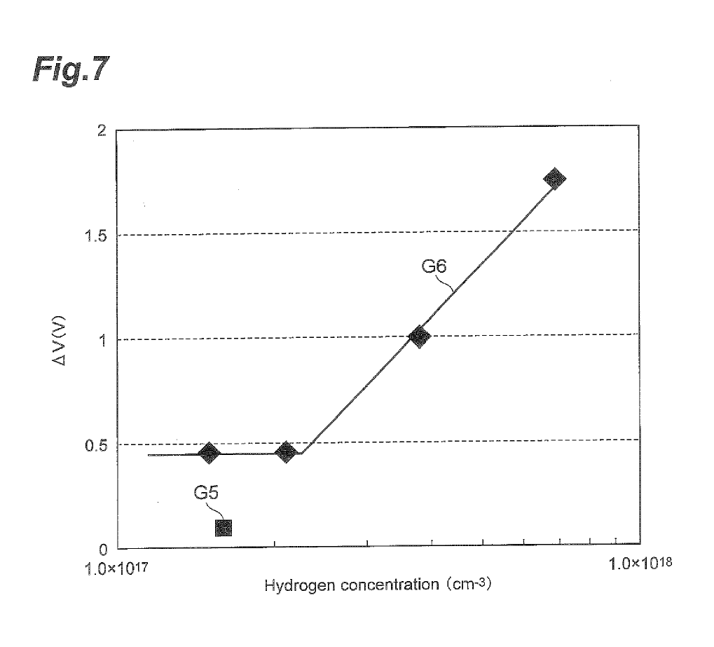

In verification 3, a correlation between operation voltage Vop and hydrogen concentration was measured in the Example and the comparative example. A result of verification 3 is illustrated in FIG. 7. The hydrogen concentration according to the measurement result of FIG. 7 is hydrogen concentration of the p-side cladding layer. The hydrogen concentration according to the measurement result of FIG. 7 was measured using SIMS. A measurement result G5 shows the measurement result of Example. A measurement result G6 shows the measurement result of the four comparative examples. The four comparative examples according to a measurement result G6 differ from one another in only the hydrogen concentration. The hydrogen concentration of Example according to the measurement result G5 is less than 2×10¹⁷ [cm⁻³]. A horizontal axis of FIG. 7 indicates the hydrogen concentration of the p-GaN cladding layer [cm⁻³]. A vertical axis of FIG. 7 indicates a difference ΔV [V] in operation voltage. A difference ΔV in operation voltage is a value obtained by subtracting the operation voltage Vop0 h when electrical energization is first started from a non-electrical energization state from the operation voltage Vop500 h after electrical energization for 500 [h] (ΔV=Vop500 h−Vop0 h).

It can be seen from the measurement result G6 that in the comparative example, the difference ΔV in operation voltage is increased with the increase in hydrogen concentration when the hydrogen concentration is equal to or more than 2×10¹⁷ [cm⁻³], whereas the difference ΔV in operation voltage is hardly changed even with the change in the hydrogen concentration when the hydrogen concentration is less than 2×10¹⁷ [cm⁻³]. That is, it is considered that the difference ΔV in operation voltage is changed due to other factors other than the hydrogen concentration when the hydrogen concentration is less than 2×10¹⁷ [cm⁻³]. Therefore, it can be seen from the measurement result G5 that the difference ΔV in operation voltage in Example is lower than that in the comparative example in which the hydrogen concentration is substantially equal to that in Example. Accordingly, it is considered from the measurement result of FIG. 7 that a factor of change in difference ΔV in operation voltage when the hydrogen concentration is less than 2×10¹⁷ [cm⁻³] is the point defects at a concentration of about 10¹⁶ [cm⁻³] (or below 10¹⁶ [cm⁻³]) as in Example, rather than at least the hydrogen concentration.

(Verification 4)

In Verification 4, a change in operation voltage according to electrical energization time was measured in Example and the comparative example. A result of Verification 4 is illustrated in FIG. 8. A measurement result G7 indicates a measurement result of Example. A measurement result G8 indicates measurement results of a plurality of (seven) comparative examples. A horizontal axis of FIG. 8 indicates the electrical energization time [h]. A vertical axis of FIG. 8 indicates the operation voltage Vop [V].

It can be seen from the result of FIG. 8 that the operation voltage Vop increases with the increase of the electrical energization time in the case of the plurality of comparative examples shown in the measurement result G8, whereas the operation voltage Vop is hardly changed even with the increase in electrical energization time in the case of Example shown in the measurement result G7. For example, it can be seen that, when the electrical energization time is 100 [h], the change in operation voltage Vop in the comparative example is much greater than that in Example.

It was seen from Verifications 2 to 4 described above that the point defects of the thermal activation energy ΔE equal to or more than about 0.1 [eV] and equal to or less than about 1.7 [eV] in Example are less than 1×10¹⁶ [cm⁻³], which is much less than in the comparative example, and the difference ΔV in operation voltage is greatly reduced and change in operation voltage Vop due to electrical energization time is small even in the case of the hydrogen concentration less than 2×10¹⁷ [cm⁻³] in which the difference ΔV in operation voltage is hardly changed even with the change of the hydrogen concentration in the related art. The inventors considered from the above that the reason of the suppression of the increase in operation voltage due to electrical energization in Example is that the point defects of the thermal activation energy ΔE (equal to or more than 0.1 [eV] and equal to or lower than 1.7 [eV]) is greatly reduced.

While a principle of the present invention has been illustrated and described in the preferred embodiment, it is recognized by those skilled in the art that the arrangement and the details in the present invention can be changed without departing from such a principle. The present invention is not limited to the specific configuration disclosed in the present embodiment. Therefore, a right of all modifications and variations derived from claims and their ideas is requested.

### REFERENCE SIGNS LIST

1 . . . nitride semiconductor light emitting element, 3 . . . ridge waveguide, 3a . . . end portion, Ep . . . epitaxial layer, L1 . . . support base, L10 . . . n-side electrode, L2 . . . n-side cladding layer, L3 . . . n-side guide layer, L4 . . . light emitting layer, L5 . . . p-side guide layer, L6 . . . p-side guide layer, L7 . . . p-side cladding layer, L8 . . . contact layer, L9 . . . p-side electrode, L9a . . . ridge portion electrode, M1 . . . n-InAlGaN support base, M2 . . . n-GaN cladding layer, M3 . . . i-InGaN guide layer, M4 . . . i-InGaN light emitting layer, M5 . . . i-InGaN guide layer, M6 . . . p-GaN guide layer, M7 . . . p-AlGaN cladding layer, M8 . . . p-GaN contact layer, Mm . . . substrate product, Nx . . . Normal direction, S1 . . . main surface.

1. A nitride semiconductor light emitting element comprising:
a support base; and
an epitaxial layer,
wherein both the support base and the epitaxial layer are composed of a hexagonal group-III nitride semiconductor,
the epitaxial layer includes a light emitting layer of a quantum well and a cladding layer and are provided on a main surface of the support base,
a p-type dopant is added to the cladding layer,
the p-type dopant is Mg,
an X-ray absorption fine structure spectrum of the cladding layer includes a first peak and a second peak,
the first peak is a first peak on the high energy side from a K absorption edge of incident X-rays,
the second peak is next to the first peak on the high energy side of the incident X-ray and is a second peak on the high energy side from the K absorption edge of the incidence X-rays, and
a ratio of a value of the first peak to a value of the second peak is in a range of 70[%] or more and 200[%] or less.

2. The nitride semiconductor light emitting element according to claim 1,
wherein the first peak in the X-ray absorption fine structure spectrum of the cladding layer is generated between 1300 [eV] and 1309 [eV] of incident X-ray energy, and
the second peak in the X-ray absorption fine structure spectrum of the cladding layer is generated between 1309 [eV] and 1320 [eV] of the incident X-ray energy.

3. The nitride semiconductor light emitting element according to claim 1,
wherein Mg concentration of the cladding layer is equal to or more than 1×10¹⁸ [cm⁻³] and equal to or less than 5×10²¹ [cm⁻³].

4. The nitride semiconductor light emitting element according to claim 1,
wherein hydrogen concentration of the cladding layer is in a range less than 2×10¹⁷ [cm⁻³], and
concentration of point defects of the cladding layer is in a range less than 1×10¹⁶ [cm⁻³].

5. The nitride semiconductor light emitting element according to claim 4,
wherein thermal activation energy of the point defects is in a range of 0.1 [eV] or more and 1.7 [eV] or less.

6. The nitride semiconductor light emitting element according to claim 1,
wherein the main surface of the support base is semi-polar, and
the main surface is inclined at an angle in any one of a range of 10° or more and 80° or less and a range of 100° or more and 170° or less with respect to a c plane of the hexagonal group-III nitride semiconductor.

7. The nitride semiconductor light emitting element according to claim 1,
wherein the main surface of the support base is semi-polar, and
the main surface is inclined at an angle in any one of a range of 63° or more and 80° or less and a range of 100° or more to 117° or less with respect to a c plane of the hexagonal group-III nitride semiconductor.

8. A nitride semiconductor light emitting element comprising:
a support base; and
an epitaxial layer,
wherein both the support base and the epitaxial layer are composed of a hexagonal group-III nitride semiconductor,
the epitaxial layer includes a light emitting layer of a quantum well and a cladding layer and are provided on a main surface of the support base,
a p-type dopant is added to the cladding layer,
the p-type dopant is Mg,
a hydrogen concentration of the cladding layer is in a range less than 2×10¹⁷ [cm⁻³], and concentration of point defects of the cladding layer is in a range less than 1×10¹⁶ [cm⁻³].

9. The nitride semiconductor light emitting element according to claim 8, wherein the Mg concentration of the cladding layer is equal to or more than 1×10¹⁸ [cm⁻³] and equal to or less than 5×10²¹ [cm⁻³].

10. The nitride semiconductor light emitting element according to claim 8,
wherein thermal activation energy of the point defects is in a range of 0.1 [eV] or more and 1.7 [eV] or less.

11. The nitride semiconductor light emitting element according to claim 8,
wherein the main surface of the support base is semi-polar, and
the main surface is inclined at an angle in any one of a range of 10° or more and 80° or less and a range of 100° or more and 170° or less with respect to a c plane of the hexagonal group-III nitride semiconductor.

12. The nitride semiconductor light emitting element according to claim 8,
wherein the main surface of the support base is semi-polar, and the main surface is inclined at an angle in any one of a range of 63° or more and 80° or less and a range of 100° or more to 117° or less with respect to a c plane of the hexagonal group-III nitride semiconductor.
